(19) United States
(12) Patent Application Publication
(10) Pub. No.: US 2026/0328866 A1
(43) Pub. Date: Oct. 22, 2026

(54) METHOD, APPARATUS AND SYSTEM FOR DETECTING TAIL CURRENT IN CURRENT TRANSFORMER (CT)

(71) Applicant: ABB Schweiz AG, Baden (CH)

(72) Inventor: Simi Valsan, Aluva (IN)

(73) Assignee: ABB Schweiz AG, Baden (CH)

(21) Appl. No.: 19/468,533

(22) Filed: Feb. 3, 2026

(30) Foreign Application Priority Data
Feb. 5, 2025 (IN) 202541009598

(51) Int. Cl. G01R 31/62; G01R 19/02

(52) U.S. Cl. CPC G01R 31/62; G01R 19/02

(57) ABSTRACT

A method for detecting tail current in CT includes obtaining real-time current values of current flowing, determining an instant time constant and a deviation value by using a pair of consecutive time constants; comparing the deviation value with predefined deviation threshold; incrementing a counter each time the deviation value is less than a predefined deviation threshold in consecutive time instances, and resetting the counter to zero when the deviation value is greater than the predefined deviation threshold. The tail current detection unit detects presence of a tail current in CT when the counter exceeds the predefined count threshold.

### CROSS-REFERENCE TO RELATED APPLICATIONS

The instant application claims priority to Indian Patent Application No. 202541009598, filed Feb. 5, 2025, which is incorporated herein in its entirety by reference.

### FIELD OF THE DISCLOSURE

The present disclosure relates to electrical engineering and, more particularly, to a method and apparatus for detecting tail current in a Current Transformer (CT).

### BACKGROUND OF THE INVENTION

Current Transformer (CT) is a device that measures electrical current flowing through a conductor or a power system. In the normal CTs (i.e., the CTs without air gap), in case of a short-circuit incident, the short-circuit current will reach tens of times or even hundreds of times the CT rated current, leading to CT saturation. In such situation, the CT cannot transfer the primary current correctly to a secondary side in the CT, which causes mis-operation or mal-operation of protection equipment and greater errors of fault location equipment. To overcome such situations, manufacturers open a small air gap on the core of CT. The air-gapped CT can guarantee that the errors are within the permissible range of the relay protection in the steady state and the transient state.

However, in the air-gapped CT, when the core flux decays to its final value after fault interruption, the energy stored in the magnetic circuit must be dissipated in the secondary circuit and results in a unidirectional discharge of long duration. Since the change in flux required to reach the remanence level is greater for the air-gapped CT, the discharge voltage is higher due to which the time of decay is very long. This results in CT secondary current tailing phenomenon, which is known as current tail. Since the time of decay is very long, this may not give an indication that the circuit breaker is open. In other words, the decay current following fault interruption may delay in indicating that the circuit breaker is open. This can cause a false operation of the breaker failure protection. In other words, the current tail may impact the operations of the breaker failure protection, which may eventually lead to generation of false alarms. Hence, it becomes necessary to mitigate the issues caused by the current tail. Therefore, there is a need to detect the current tail in the CT to avoid false alarms.

### BRIEF SUMMARY OF THE INVENTION

Disclosed herein is a method of detecting tail current in a Current Transformer (CT). The method comprises obtaining real-time current values of current flowing in a secondary side of the CT. Further, the method comprises determining an instant time constant (Kₜ). The instant time constant (Kₜ) is ratio of instant current value (Iₜ) at a specific time instance (t) and current value (Iₜ₋₁) at preceding time instance (t−1). Thereafter, the method comprises determining a deviation value (ΔKₜ) by using pair of consecutive time constants. The pair of consecutive time constants are the instant time constant (Kₜ) at the specific time instance (t) and a time constant (Kₜ₋₁) at preceding time instance (t−1). Furthermore, the method comprises comparing the deviation value (ΔKₜ) with a predefined deviation threshold to determine whether the deviation value (ΔKₜ) is less than the predefined deviation threshold. Thereafter, based on comparison, the method comprises performing one of, incrementing a counter each time when the deviation value (ΔK₁) is less than the predefined deviation threshold in consecutive time instances and resetting the counter to zero when the deviation value (ΔK₁) is greater than the predefined deviation threshold. Finally, the method comprises detecting presence of tail current in the CT when the counter exceeds a predefined count threshold.

Further, disclosed herein is a tail current detection unit for detecting tail current in a Current Transformer (CT). The tail current detection unit comprises a processor and a memory. The memory is communicatively coupled to the processor and stores processor-executable instructions, which on execution, cause the processor to obtain real-time current values of current flowing in a secondary side of the CT. Further, the processor determines an instant time constant (K₁). The instant time constant (K₁) is ratio of instant current value (Iₜ) at a specific time instance (t) and current value (Iₜ₋₁) at preceding time instance (t−1). Thereafter, the processor determines a deviation value (ΔKₜ) by using pair of consecutive time constants. The pair of consecutive time constants are the instant time constant (K₁) at the specific time instance (t) and a time constant (Kₜ₋₁) at preceding time instance (t−1). Furthermore, the processor compares the deviation value (ΔKₜ) with a predefined deviation threshold to determine whether the deviation value (ΔKₜ) is less than the predefined deviation threshold. Thereafter, based on comparison, the processor performs one of, incrementing a counter each time when the deviation value (ΔKₜ) is less than the predefined deviation threshold in consecutive time instances and resetting the counter to zero when the deviation value (ΔKₜ) is greater than the predefined deviation threshold. Finally, the processor detects presence of tail current in the CT when the counter exceeds a predefined count threshold.

Furthermore, disclosed herein is an Intelligent Electronic Device (IED) for detecting tail current in a Current Transformer (CT). The IED comprises an Analog to Digital Converter (ADC), a system measurement, one or more protection functions, and a tail current detection unit. The tail current detection unit is configured to obtain real-time current values of current flowing in a secondary side of the CT. The real-time current values are measurements of current. Further, the tail current detection unit determines an instant time constant (Kₜ). The instant time constant (Kₜ) is ratio of instant current value (Iₜ) at a specific time instance (t) and current value (Iₜ₋₁) at preceding time instance (t−1). Thereafter, the tail current detection unit determines a deviation value (ΔKₜ) by using pair of consecutive time constants. The pair of consecutive time constants are the instant time constant (K₁) at the specific time instance (t) and a time constant (Kₜ₋₁) at preceding time instance (t−1). Furthermore, the tail current detection unit compares the deviation value (ΔK₁) with a predefined deviation threshold to determine whether the deviation value (ΔK₁) is less than the predefined deviation threshold. Thereafter, based on comparison, the tail current detection unit performs one of, incrementing a counter each time when the deviation value (ΔK₁) is less than the predefined deviation threshold in consecutive time instances and resetting the counter to zero when the deviation value (ΔK₁) is greater than the predefined deviation threshold. Finally, the tail current detection unit detects presence of tail current in the CT when the counter exceeds a predefined count threshold.

### BRIEF DESCRIPTION OF THE SEVERAL VIEWS OF THE DRAWING(S)

FIG. 1A is a diagram of an exemplary architecture to implement techniques for detecting tail current in a Current Transformer (CT) in accordance with some embodiments of the present disclosure.

FIG. 1B is a block diagram of an exemplary architecture having an Intelligent Electronic Device (IED) comprising an tail current detection unit, in accordance with some embodiments of the present disclosure.

FIG. 1C is a block diagram of an exemplary architecture comprising a tail current detection unit, a switch, and breaker failure protection, in accordance with some embodiments of the present disclosure.

FIG. 2 is a set of time-aligned graphs illustrating current, instant time constant (Kₜ), a deviation value (ΔKₜ), and current tail indication, in accordance with some embodiments of the present disclosure.

Each of FIGS. 3A, 3B, 3C, and 3D shows a set of before/after graphs comparing issuing of re-trip/backup trip signals in an existing implementation (before) and in a present implementation (after), in accordance with some embodiments of the present disclosure.

FIG. 4 is a detailed block diagram of a tail current detection unit for detecting tail current in a Current Transformer (CT), in accordance with some embodiments of the present disclosure.

FIG. 5 is a flowchart illustrating a method of detecting tail current in a Current Transformer (CT), in accordance with some embodiments of the present disclosure.

### DETAILED DESCRIPTION OF THE INVENTION

In the present document, the word “exemplary” is used herein to mean “serving as an example, instance, or illustration.” Any embodiment or implementation of the present subject matter described herein as “exemplary” is not necessarily to be construed as preferred or advantageous over other embodiments. While the disclosure is susceptible to various modifications and alternative forms, specific embodiment thereof has been shown by way of example in the drawings and will be described in detail below. It should be understood, however that it is not intended to limit the disclosure to the specific forms disclosed, but on the contrary, the disclosure is to cover all modifications, equivalents, and alternative falling within the scope of the disclosure.

The terms “comprises”, “comprising”, “includes”, or any other variations thereof, are intended to cover a non-exclusive inclusion, such that a setup, device, or method that comprises a list of components or steps does not include only those components or steps but may include other components or steps not expressly listed or inherent to such setup or device or method. In other words, one or more elements in a system or apparatus proceeded by “comprises . . . a” does not, without more constraints, preclude the existence of other elements or additional elements in the system or method.

As outlined in the background section, instantaneous current in a Current Transformer (CT) excitation branch and secondary winding may not be zero at the moment that the primary device cut off. The energy storage in the inductance will slowly release through a secondary circuit formed by resistance and inductance. This results in the CT secondary current tailing phenomenon, which is known as current tail. Since the inductance is large, a damp time constant of the secondary circuit is large, usually several hundred milliseconds to a few seconds. The CT tail current is mainly consisting of a damping aperiodic component. As the decay current following fault interruption may delay in indicating that the circuit breaker is open, this may cause false operation interrupting complete power system. The present disclosure proposes method and device to detect the tail current in the CT to avoid the scenario of false alarms.

According to the present disclosure, an Intelligent Electronic Device (IED) for detecting tail current in a Current Transformer (CT) is disclosed. The IED comprises an Analog to Digital Converter (ADC), a system measurement, one or more protection functions, and a tail current detection unit. The tail current detection unit may obtain real-time current values of current flowing in a secondary side of the CT. The real-time current values are measurements of current. Upon obtaining the real-time current values, the tail current detection unit may determine an instant time constant (Kₜ). The instant time constant (Kₜ) may be ratio of instant current value (Iₜ) at a specific time instance (t) and current value (Iₜ₋₁) at preceding time instance (t−1). Thereafter, the tail current detection unit may compare the deviation value (ΔKₜ) with a predefined deviation threshold to determine whether the deviation value (ΔKₜ) is less than the predefined deviation threshold. Based on the comparison, the tail current detection unit may perform one of, incrementing a counter each time when the deviation value (ΔKₜ) is less than the predefined deviation threshold in consecutive time instances and resetting the counter to zero when the deviation value (ΔKₜ) is greater than the predefined deviation threshold. Finally, the tail current detection unit may detect presence of tail current in the CT when the counter exceeds a predefined count threshold. The present disclosure also detects end of tail current, which is discussed below in detail.

In the following detailed description of the embodiments of the disclosure, reference is made to the accompanying drawings that form a part hereof, and in which are shown by way of illustration specific embodiments in which the disclosure may be practiced. These embodiments are described in sufficient detail to enable those skilled in the art to practice the disclosure, and it is to be understood that other embodiments may be utilized and that changes may be made without departing from the scope of the present disclosure. The following description is, therefore, not to be taken in a limiting sense.

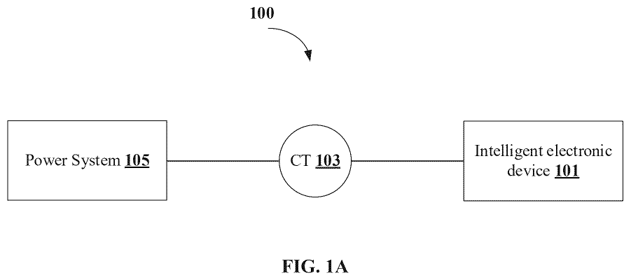

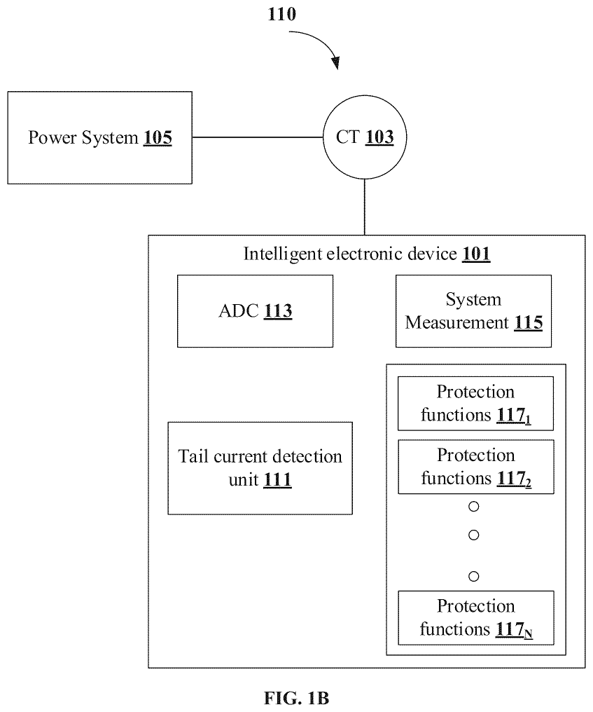

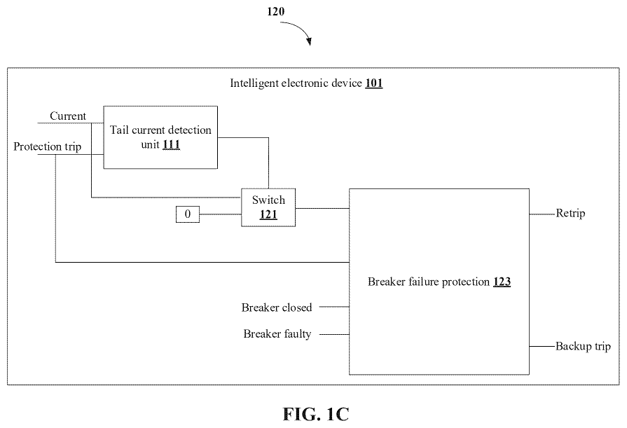

FIG. 1A shows an exemplary architecture 100 to implement techniques for detecting tail current in a Current Transformer (CT), in accordance with some embodiments of the present disclosure.

The exemplary architecture 100 comprises an Intelligent Electronic Device (IED) 101, a Current Transformer (CT) 103 and a power system 105. In an embodiment, the IED 101 may be electrically coupled with the CT 103. In an embodiment, the CT 103 may be configured to measure electrical current flowing through a power system 105. In an embodiment, the power system 105 may be a network of electrical components designed to generate, transmit, and distribute electrical energy. In some embodiments, the power system 105 may be an electrical system or a combination of electrical systems. As an example, the power system 105 may be, without limitation, an electrical grid, an on-grid solar power system, a hybrid power system, In an embodiment, the CT 103 may be electrically coupled with the power system 105 to obtain real-time current values of current flowing through the power system 105.

FIG. 1B illustrates an exemplary architecture of the IED 101. The IED 101 may be alternatively referred as a relay which can detect, monitor and control a power system. The IED 101 issues TRIP commands to a circuit breaker on detecting fault conditions. The IED 101 may include, without limitation, a tail current detection unit 111, an Analog to Digital Converter (ADC) 113, a system measurement 115 and one or more protection functions 117_{N}. The ADC 113 may be used to convert analog current signals from the CT 103 to digital values. The system measurement 115 may be used for protection of power system 105, monitoring and controlling of the power system 105, and data logging and analysis in the IED 101. The one or more protection functions 117_{N} may be used for protection of the power system 105 associated with the IED 101. In an embodiment, the IED 101 may be configured to detect tail current in the CT 103 using the tail current detection unit 111. The IED 101 may be used as a standalone system or as an application to perform an action disclosed in present disclosure.

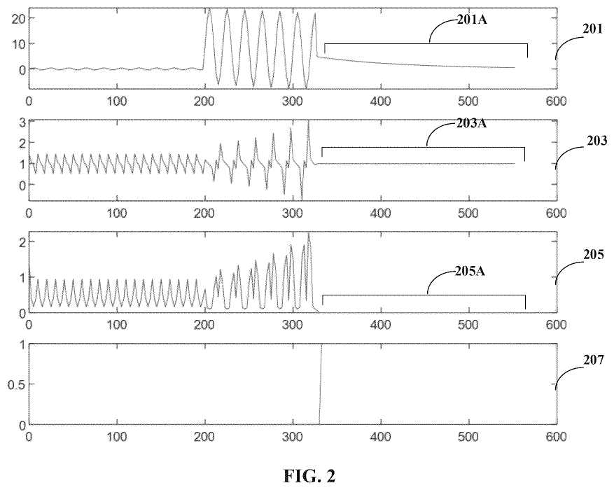

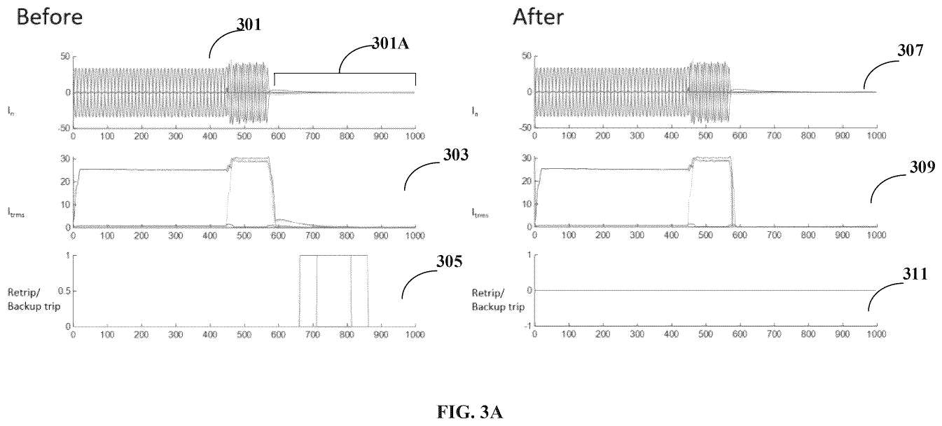

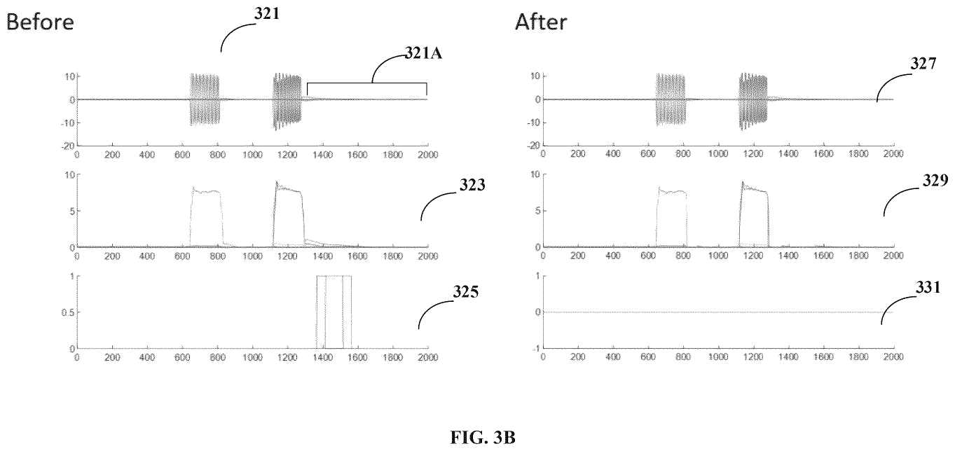

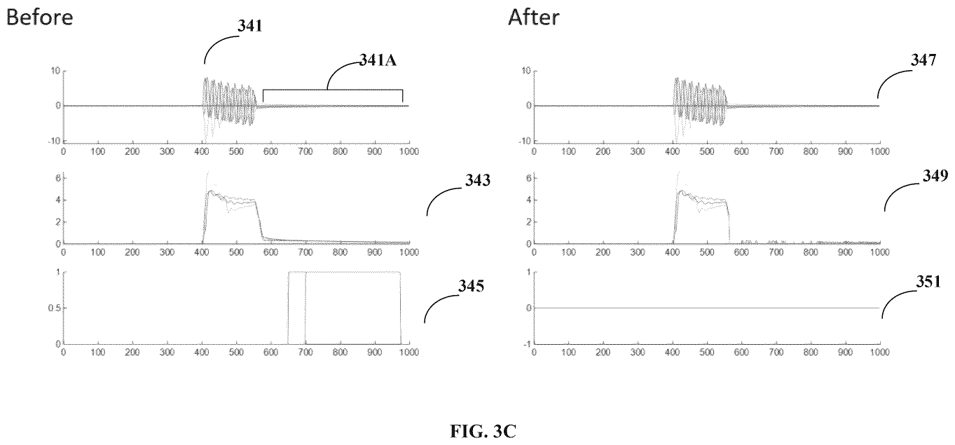

In an embodiment, the tail current detection unit 111 may be configured to obtain real-time current values of current flowing in a secondary side of the CT 103. The real-time current values are measurements of the current. In an embodiment, the secondary side of the CT 103 provides measurement of the real-time current flowing in the power system 105. In an embodiment, the tail current detection unit 111 may obtain the real-time measurements upon activation of a trip signal by the one or more protection functions 117_{N} of the IED 101. The IED 101 may be electrically coupled with the CT 103 (as illustrated in FIG. 1). In an embodiment, the one or more protection functions 117_{N} may be used for protection of the power system 105 associated with the IED 101. As an example, the one or more protection functions 117_{N} may include, without limitation, overcurrent protection, earth fault protection, differential protection, distance protection, voltage protection, frequency protection and power swing protection. In an embodiment, the activation of trip signal may indicate an abnormal condition or fault which may be required to be addressed. FIG. 2 illustrates exemplary graphs, graph 201 in FIG. 2 illustrates the real-time current values of current flowing in a secondary side of the CT 103. The current tail i.e., a decaying waveform that resembles a tail is represented by 201A in FIG. 2.

Referring back to FIG. 1A, upon obtaining the real-time current values, the tail current detection unit 111 may determine an instant time constant (Kₜ). The instant time constant (Kₜ) may be ratio of instant current value (Iₜ) at a specific time instance (t) and current value (Iₜ₋₁) at preceding time instance (t−1). In an embodiment, the preceding time instance (t−1) may be a time instance which is prior to the specific time instance (t). As an example, time difference between the specific time instance (t) and the preceding time instance (t−1) may be in a range of 500 microseconds to 1.5 milliseconds. The value of the time difference should not be construed as a limitation and the value of the time difference may vary. As an example, the instant time constant (Kₜ) may be ratio of current value at time 10 milliseconds and current value at time 9 milliseconds. As an example, equation 1 below shows the instant time constant (Kₜ):

Kₜ=Iₜ/Iₜ₋₁ (1)

The Equation 1 provided above is intended as an illustrative example and should not be construed as a limitation of the present disclosure. The graph 203 of FIG. 2 illustrates the instant time constant determined using the current values. In an embodiment, the instant time constant (K₁) may be determined continuously as the values may be used for further determination.

In an embodiment, upon determining the instant time constant (K₁), the tail current detection unit 111 may be configured to determine a deviation value (ΔK₁) by using pair of consecutive time constants. The pair of consecutive time constants may be the instant time constant (Kₜ) at the specific time instance (t) and a time constant (Kₜ₋₁) at preceding time instance (t−1). Similar to determining the instant time constant (K₁), the deviation value (ΔKₜ) may be determined using difference between the instant time constant (K₁) at the specific time instance (t) and the time constant (Kₜ₋₁) at preceding time instance (t−1). In an embodiment, as the values of the instant time constant (K₁) are determined continuously, the deviation value (ΔK₁) may be determined using difference between the instant time constant (K₁) at the specific time instance (t) and the time constant (Kₜ₋₁) at preceding time instance (t−1). As an example, equation 2 below shows the deviation value (ΔKₜ):

ΔKₜ=|Kₜ−Kₜ₋₁| (2)

The Equation 2 provided above is intended as an illustrative example and should not be construed as a limitation of the present disclosure. The graph 205 of FIG. 2 illustrates the deviation value (ΔK₁) determined using the instant time constant values. In an embodiment, the deviation value (ΔK₁) may be determined continuously as the values may be used for further determination. In an embodiment, the real-time current values may vary based on the power system 105, due to which the instant time constant (K₁) may also vary. Since, the instant time constant (K₁) may vary, determining the current tail based on the instant time constant (K₁) may be difficult as the constant value which indicates the current tail may not be defined. For instance, referring to graph 203 in FIG. 2, which indicates instant time constant (K₁) of the current tail is at a value ‘1’, i.e., the straight line 203A indicating current tail time constant is constant at value ‘1’. In other words, normal working of the CT 103 may be identified based on a sinusoidal waves in the graph. Since the current tail is formed due to decay of the current in the secondary side of the CT 103, this may be identified based on a decaying line that reflects a consistent reduction over time.

To overcome the challenges faced in detecting current tail, the tail current detection unit 111 may determine the deviation value (ΔKₜ). This may help in indicating the current tail as the deviation value (ΔK₁) may be closer to zero because the deviation value (ΔKₜ) is determined based on the difference between the instant time constant (Kₜ) at the specific time instance (t) and the time constant (Kₜ₋₁) at preceding time instance (t−1). These time constants would be approximately same, leading to near-zero deviation value. Referring to graph 207 of FIG. 2, the current tail is closer to zero which simplifies the process of detecting the current tail.

In an embodiment, upon determining the deviation value (ΔKₜ), the tail current detection unit 111 may be configured to compare the deviation value (ΔK₁) with a predefined deviation threshold to determine whether the deviation value (ΔKₜ) is less than the predefined deviation threshold. As an example, the predefined deviation threshold may be, 0.02 per unit.

In an embodiment, based on the comparison, the tail current detection unit 111 may increment a counter each time when the deviation value (ΔKₜ) may be less than the predefined deviation threshold in consecutive time instances. Else, the tail current detection unit 111 may reset the counter to zero when the deviation value (ΔKₜ) may be greater than the predefined deviation threshold. As an example, consider an exemplary scenario in which the deviation value (ΔKₜ) is less than the predefined deviation threshold for two consecutive time instances, however, in the third time instance, the deviation value (ΔK₁) is greater than the predefined deviation threshold. In such scenario, the counter is reset to zero. In other words, the counter is reset to zero whenever the deviation value (ΔK₁) is greater than the predefined deviation threshold. The counter is reset to zero to restart the counter when the deviation value (ΔKₜ) may be less than the predefined deviation threshold in consecutive time instances. This process is continuously performed upon the comparison.

In an embodiment, the tail current detection unit 111 may detect presence of tail current in the CT 103 when the counter exceeds a predefined count threshold. As an example, the predefined count threshold may be, without limitation, eight. In some embodiments, the presence of tail current in the CT 103 may be detected when the deviation value (ΔK₁) may be less than the predefined deviation threshold for a predefined duration. As an example, the predefined duration may be, without limitation, 5 milliseconds. As illustrated in graph 207 of FIG. 2, the detection of current tail is indicated as the value changes to “1” from “0”. In an embodiment, upon detecting the current tail, the tail current detection unit 111 may activate an output signal to indicate the presence of tail current. The output signal enables a switch 121 to supply a value “zero”, instead of the current flowing in secondary side of the CT 103, to one or more components using information of the current flowing in the secondary side of the CT 103. The “zero” value is supplied to avoid generation of false alarms. If the actual current flowing in the secondary side of the CT is supplied, then the false alarms are generated as the one or more components would sense the decaying current and may generate alarms.

Referring to FIG. 1C, which shows an exemplary illustration of the IED 101, with tail current detection unit 111, a switch 121 and a breaker failure protection 123. In an embodiment, the switch 121 may be a logical component of the IED 101, which may be activated to supply the value “zero” to one or more components in the secondary side of the CT 103 when the current tail is detected. In other words, in an ideal scenario, the one or more components may use the information of the current flowing in the secondary side of the CT 103. When the current tail is detected, the output signal of the switch 121 may be activated to supply “zero”, instead of the actual current (i.e., tail current) flowing in secondary side of the CT 103 (shown in FIG. 1C) to avoid false alarm generation.

In an embodiment, end of the current tail may be determined by the tail current detection unit 111 by determining a Root Mean Square (RMS) value of the current flowing in the secondary side of the CT 103. Further, the tail current detection unit 111 may determine end of the tail current in the CT 103, when the RMS value of the current is substantially zero. The RMS may be determined using known methods. In an embodiment, upon detecting end of the current tail, the tail current detection unit 111 may reset the counter value to zero. Further, the tail current detection unit 111 may deactivate the output signal upon detection of the end of the tail current. The deactivation of the output signal may be stopping the supply of “zero” to the one or more components, which use the information of the current flowing in the secondary side of the CT 103. When the output signal is deactivated, the current flowing in the secondary side of the CT 103 may be supplied to one or more components, which use information of the current flowing in the secondary side of the CT 103.

Referring to graphs shown in FIGS. 3A-3D, as shown in the graphs 301, 321, 341 and 361 the current tail is represented using 301A, 321A, 341A and 361A respectively. The current tail can also be illustrated in graphs 303, 323, 343 and 363. The graphs 301-305, 321-325, 341-345 and 361-365 are related to absence of tail current detection. The graphs 307-311, 327-331, 347-351 and 367-371 are related to proposed technique. In the existing implementations, a re-trip or a backup-trip is issued since the current still remains in secondary side of the CT 103 (refer graphs 305, 325, 345 and 365) and it is passed to the one or more components using information of the current flowing in the secondary side of the CT. However, using the tail current detection unit 111, the “zero” value is supplied to one or more components using information of the current flowing in the secondary side of the CT (i.e., the current tail is truncated (refer graphs 309, 329, 349 and 369)), this will avoid the issue of the re-trip or the backup-trip which may generate false alarms (refer graphs 311, 331, 351 and 371).

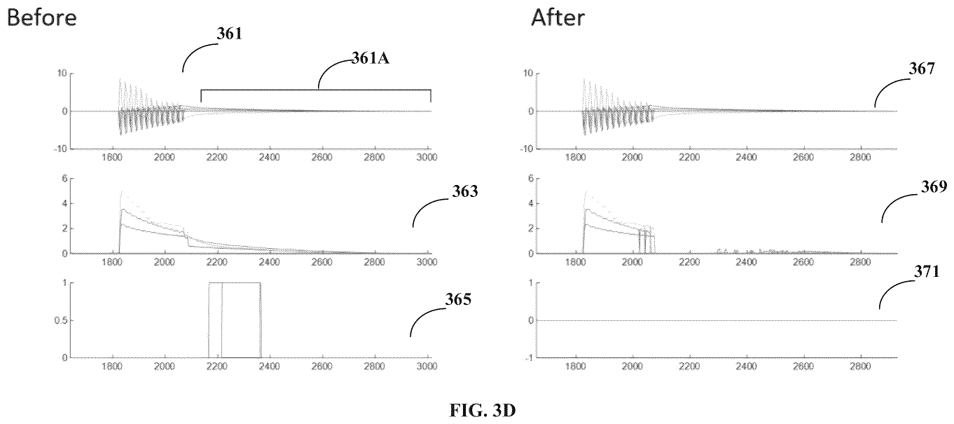

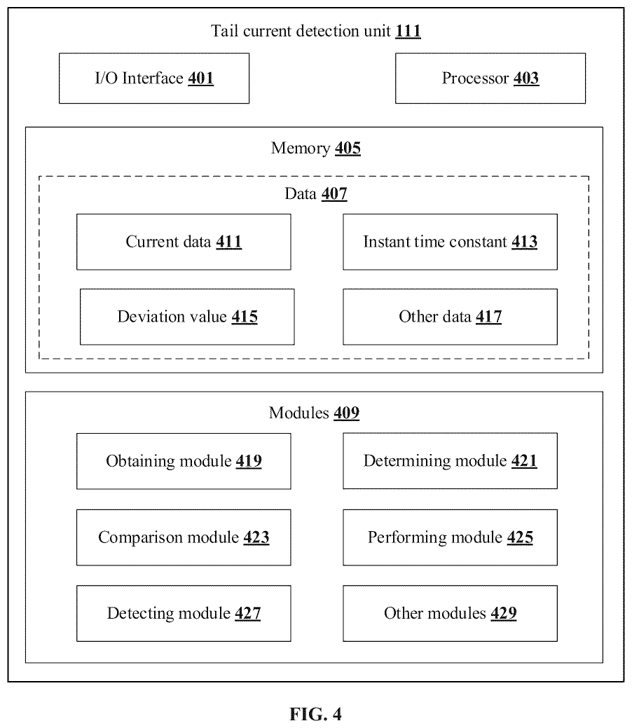

FIG. 4 shows a detailed block diagram of a tail current detection unit 111 for detecting tail current in a Current Transformer (CT) 103, in accordance with some embodiments of the present disclosure.

In some implementations, the tail current detection unit 111 may include an I/O interface 401, a processor 403 and a memory 405. In an embodiment, the memory 405 may be communicatively coupled to the processor 403. The processor 403 may be configured to perform one or more functions of the tail current detection unit 111 to detect tail current in a Current Transformer (CT) 103, using the data 407 and the one or more modules 409 of the tail current detection unit 111. In an embodiment, the memory 405 may store data 407.

In an embodiment, the data 407 stored in the memory 405 may include, without limitation, current data 411, instant time constant 413, deviation value 415 and other data 417. In some implementations, the data 407 may be stored within the memory 405 in the form of various data structures. Additionally, the data 407 may be organized using data models, such as relational or hierarchical data models. The other data 417 may include various temporary data and files generated by the one or more modules 409.

In an embodiment, the current data 411 may indicate real-time current values of current flowing in a secondary side of the CT 103. In an embodiment, the current data 411 may be obtained using current sensor configured on the secondary side of the CT 103. In some embodiments, the current data 411 may be determined based on the current value, voltage value and number of windings at primary and secondary side of the CT 103. The current data 411 may be used to detect the current tail.

In an embodiment, the instant time constant 413 may be a value determined based on a ratio of instant current value (Iₜ) at a specific time instance (t) and current value (Iₜ₋₁) at preceding time instance (t−1). In other words, the instant time constant 413 may be determined using the current data 411. The instant time constant 413 may be determined continuously as consecutive values of the instant time constant 413 may be used to determine the deviation value 415. The instant time constant 413 may be determined using the equation 1.

In an embodiment, the deviation value 415 may be a value determined using pair of consecutive time constants. In an embodiment, the pair of consecutive time constants may be the instant time constant (Kₜ) at the specific time instance (t) and a time constant (Kₜ₋₁) at preceding time instance (t−1). In other words, the deviation value 415 may be determined using the instant time constant 413. The deviation value (ΔKₜ) may be determined using difference between the instant time constant (Kₜ) at the specific time instance (t) and a time constant (Kₜ₋₁) at preceding time instance (t−1). The deviation value 415 may be determined continuously as the deviation value 415 may be used to detect the current tail. The deviation value 415 may be determined using the equation 2.

In an embodiment, the data 407 may be processed by one or more modules 409 of the tail current detection unit 111. In some implementations, the one or more modules 409 may be communicatively coupled to the processor 403 for performing one or more functions of the tail current detection unit 111. In an implementation, the one or more modules 409 may include, without limiting to, an obtaining module 419, a determining module 421, a comparison module 423, a performing module 425, a detecting module 427 and other modules 429.

As used herein, the term module may refer to an Application Specific Integrated Circuit (ASIC), an electronic circuit, a hardware processor (shared, dedicated, or group) and memory that execute one or more software or firmware programs, a combinational logic circuit, and/or other suitable components that provide the described functionality. In an implementation, each of the one or more modules 409 may be configured as stand-alone hardware computing units. In an embodiment, the other modules 429 may be used to perform various miscellaneous functionalities on the tail current detection unit 111. It will be appreciated that such one or more modules 409 may be represented as a single module or a combination of different modules.

In an embodiment, the obtaining module 419 may be configured for obtaining real-time current values of current flowing in a secondary side of the CT 103. The real-time current values are measurements of current.

In an embodiment, the determining module 421 may be configured for determining an instant time constant (Kₜ). The instant time constant (Kₜ) may be a ratio of instant current value (Iₜ) at a specific time instance (t) and current value (Iₜ₋₁) at preceding time instance (t−1).

In an embodiment, the determining module 421 may be configured for determining a deviation value (ΔKₜ) by using pair of consecutive time constants. The pair of consecutive time constants may be the instant time constant (Kₜ) at the specific time instance (t) and a time constant (Kₜ₋₁) at preceding time instance (t−1).

In an embodiment, the comparison module 423 may be configured for comparing the deviation value (ΔKₜ) with a predefined deviation threshold to determine whether the deviation value (ΔKₜ) is less than the predefined deviation threshold.

In an embodiment, the performing module 425 may be configured for performing one of, incrementing a counter each time when the deviation value (ΔKₜ) is less than the predefined deviation threshold in consecutive time instances and resetting the counter to zero when the deviation value (ΔKₜ) is greater than the predefined deviation threshold.

In an embodiment, the detecting module 427 may be configured for detecting presence of tail current in the CT 103 when the counter exceeds a predefined count threshold. In an embodiment, upon detecting the presence of tail current in the CT 103, an output signal may be activated to indicate the presence of tail current. The output signal enables a switch 121 to supply a value “zero”, instead of the current flowing in secondary side of the CT 103, to one or more components using information of the current flowing in the secondary side of the CT 103. In an embodiment, the determining module 421 may be configured for determining a Root Mean Square (RMS) value of the current flowing in the secondary side of the CT 103. Further, the determining module 421 may be configured for determining end of the tail current in the CT 103, when the RMS value of the current is substantially zero. In an embodiment, upon determining the end of the tail current, a counter value may be reset to zero. Further, the output signal may be deactivated to indicate the end of the tail current. When the output signal is deactivated, the current flowing in the secondary side of the CT 103 is supplied to one or more components using information of the current flowing in the secondary side of the CT 103.

Consider an exemplary working of the present disclosure with example values. The obtaining module 419 obtains current value at three time instances, i.e., t, t−1 and t−2. The corresponding current values at the time instances are given below:
Iₜ=3.63536
Iₜ₋₁=3.65816
Iₜ₋₂=3.68109

Further, the determining module 421 may determine the instant time constant (Kₜ). The determining module 421 determines the instant time constant (Kₜ) at two time instances, i.e., t, t−1. The instant time constants are provided below:

kₜ=Iₜ/Iₜ₋₁=3.63536/3.65816=0.993769

kₜ₋₁=Iₜ₋₁/Iₜ₋₂=3.65816/3.68109=0.993769

Upon determining the instant time constant (Kₜ), the determining module 421 may determine the deviation value (ΔKₜ) by using pair of consecutive time constants. The deviation value (ΔKₜ) is provided below:

Δkₜ=kₜ−kₜ₋₁=0

In an embodiment, the performing module 425 may increment the counter each time when the deviation value (ΔKₜ) is less than the predefined deviation threshold in consecutive time instances. In an embodiment, the detecting module 427 may detect presence of tail current in the CT 103 when the counter exceeds a predefined count threshold. Upon detecting the presence of the current tail, the output signal may be activated to indicate the presence of tail current. The output signal enables a switch 121 to supply a value “zero”, instead of the current flowing in secondary side of the CT 103, to one or more components using information of the current flowing in the secondary side of the CT 103. The supply of the current is stopped as there is no supply of current from primary side of the CT 103 and the current which is received may be decay current.

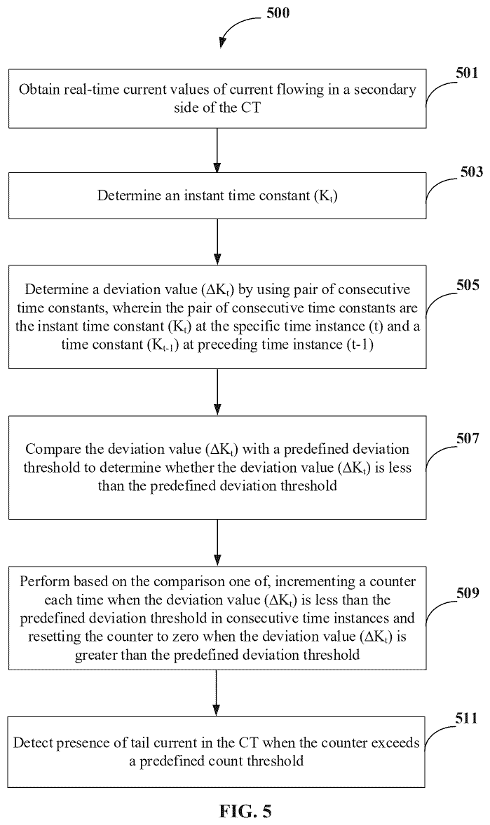

FIG. 5 shows a flowchart illustrating a method of detecting tail current in a Current Transformer (CT) 103, in accordance with some embodiments of the present disclosure.

As illustrated in FIG. 5, the method 500 may include one or more blocks illustrating a method of detecting tail current in a CT 103 using a tail current detection unit 111 illustrated in FIG. 4. The method 500 may be described in the general context of computer executable instructions. Generally, computer executable instructions can include routines, programs, objects, components, data structures, procedures, modules, and functions, which perform specific functions or implement specific abstract data types.

The order in which the method 500 is described is not intended to be construed as a limitation, and any number of the described method blocks can be combined in any order to implement the method. Additionally, individual blocks may be deleted from the methods without departing from the scope of the subject matter described herein. Furthermore, the method can be implemented in any suitable hardware, software, firmware, or combination thereof.

At block 501, the method 500 includes obtaining, by a processor 403 associated with the tail current detection unit 111, real-time current values of current flowing in a secondary side of the CT 103. The real-time current values are measurements of current. In an embodiment, the real-time measurements may be obtained upon activation of a trip signal by one or more protection functions 117_{N} in Intelligent Electronic Device (IED) 101. The IED 101 may be electrically coupled with the CT 103.

At block 503, the method 500 includes determining, by the processor 403, an instant time constant (Kₜ). The instant time constant (Kₜ) may be ratio of instant current value (Iₜ) at a specific time instance (t) and current value (Iₜ₋₁) at preceding time instance (t−1).

At block 505, the method 500 includes determining, by the processor 403, a deviation value (ΔKₜ) by using pair of consecutive time constants. The pair of consecutive time constants may be the instant time constant (Kₜ) at the specific time instance (t) and a time constant (Kₜ₋₁) at preceding time instance (t−1).

At block 507, the method 500 includes comparing, by the processor 403, the deviation value (ΔKₜ) with a predefined deviation threshold to determine whether the deviation value (ΔKₜ) is less than the predefined deviation threshold.

At block 509, based on comparison the method 500 includes performing, by the processor 403, one of, incrementing a counter each time when the deviation value (ΔKₜ) is less than the predefined deviation threshold in consecutive time instances and resetting the counter to zero when the deviation value (ΔKₜ) is greater than the predefined deviation threshold.

At block 511, the method 500 includes detecting, by the processor 403, presence of tail current in the CT 103 when the counter exceeds a predefined count threshold. In an embodiment, the processor 403 may activate an output signal to indicate the presence of tail current. The output signal enables a switch 121 to supply a value “zero”, instead of the current flowing in secondary side of the CT 103, to one or more components using information of the current flowing in the secondary side of the CT 103. In an embodiment, the processor 403 may determine a Root Mean Square (RMS) value of the current flowing in the secondary side of the CT 103. Further, the processor 403 may determine end of the tail current in the CT 103, when the RMS value of the current is substantially zero. Thereafter, the processor 403 may reset a counter value to zero upon determining the end of the tail current. Finally, the processor 403 may deactivate an output signal to indicate the end of the tail current. When the output signal is deactivated, the current flowing in the secondary side of the CT 103 may be supplied to one or more components using information of the current flowing in the secondary side of the CT 103. The processor 403 may detect the tail current in a timely manner to avoid generation of false alarms and false operations caused by the tail current.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

Referral Numerals:

| Reference Number | Description |
|---|---|
| 100 | Architecture |
| 101 | Intelligent Electronic Device (IED) |
| 103 | Current Transformer (CT) |
| 105 | Power system |
| 111 | Tail current detection unit |
| 113 | Analog to Digital Converter (ADC) |
| 115 | System measurements |
| 121 | Switch |
| 123 | Breaker failure protection |
| 401 | I/O Interface |
| 403 | Memory |
| 405 | Data |
| 407 | Processor |
| 409 | Modules |
| 411 | Current data |
| 413 | Instant time constant |
| 415 | Deviation value |
| 417 | Other data |
| 419 | Obtaining module |
| 421 | Determining module |
| 423 | Comparison module |
| 425 | Performing module |
| 427 | Detecting module |
| 429 | Other modules |

What is claimed is:

1. A method of detecting tail current in a Current Transformer (CT), the method comprising:
obtaining real-time current values of current flowing in a secondary side of the CT;
determining an instant time constant, wherein the instant time constant is a ratio of an instant current value at a specific time instance and a current value at a preceding time instance;
determining a deviation value based on a pair of consecutive time constants, wherein the pair of consecutive time constants are the instant time constant at the specific time instance and a time constant at the preceding time instance;
comparing the deviation value with a predefined deviation threshold to determine whether the deviation value is less than the predefined deviation threshold; and
based on the comparison, performing one of:
incrementing a counter each time when the deviation value is less than the predefined deviation threshold in consecutive time instances; and/or
resetting the counter to zero when the deviation value is greater than the predefined deviation threshold; and/or
detecting presence of tail current in the CT when the counter exceeds a predefined count threshold.

2. The method as claimed in claim 1, further comprising activating an output signal to indicate the presence of tail current, wherein the output signal enables a switch to supply a value “zero”, instead of the current flowing in secondary side of the CT, to one or more components using information of the current flowing in the secondary side of the CT.

3. The method as claimed in claim 1, further comprising determining a Root Mean Square value of the current flowing in the secondary side of the CT; and determining end of the tail current in the CT when the RMS value of the current is substantially zero.

4. The method as claimed in claim 3, further comprising resetting a counter value to zero upon determining the end of the tail current; and deactivating an output signal to indicate the end of the tail current, wherein when the output signal is deactivated, the current flowing in the secondary side of the CT is supplied to one or more components using information of the current flowing in the secondary side of the CT.

5. The method as claimed in claim 1, wherein the real-time measurements are obtained upon activation of a trip signal by one or more protection functions in a relay that is electrically coupled with the CT.

6. A tail current detection unit for detecting tail current in Current Transformer (CT), the tail current detection unit comprising a processor; and a memory communicatively coupled to the processor, wherein the memory stores processor instructions, which, on execution, causes the processor to:
obtain real-time current values of current flowing in a secondary side of the CT;
determine an instant time constant;
wherein the instant time constant is a ratio of an instant current value at a specific time instance and at a current value at a preceding time instance;
determine a deviation value by using a pair of consecutive time constants, wherein the pair of consecutive time constants are the instant time constant at the specific time instance and a time constant at the preceding time instance;
compare the deviation value with a predefined deviation threshold to determine whether the deviation value is less than the predefined deviation threshold;
based on the comparison, perform one of:
increment a counter each time when the deviation value is less than the predefined deviation threshold in consecutive time instances; and/or
reset the counter to zero when the deviation value (ΔKₜ) is greater than the predefined deviation threshold; and/or
detect presence of tail current in the CT when the counter exceeds a predefined count threshold.

7. The tail current detection unit as claimed in claim 6, wherein the processor is further configured to activate an output signal to indicate the presence of tail current, wherein the output signal enables a switch to supply a value “zero”, instead of the current flowing in secondary side of the CT, to one or more components using information of the current flowing in the secondary side of the CT.

8. The tail current detection unit as claimed in claim 6, wherein the processor is further configured to determine a Root Mean Square (RMS) value of the current flowing in the secondary side of the CT; and determine end of the tail current in the CT, when the RMS value of the current is substantially zero.

9. The tail current detection unit as claimed in claim 8, wherein the processor is further configured to reset a counter value to zero upon determining the end of the tail current; and deactivate output signal to indicate the end of the tail current, wherein when the output signal is deactivated, the current flowing in the secondary side of the CT is supplied to one or more components using information of the current flowing in the secondary side of the CT.

10. The tail current detection unit as claimed in claim 6, wherein the processor obtains real-time measurements upon activation of a trip signal by one or more protection functions in a relay that is electrically coupled with the CT.

11. An Intelligent Electronic Device (IED) for detecting tail current in Current Transformer (CT), the IED comprising:
an Analog to Digital Converter;
a system measurement;
one or more protection functions; and
a tail current detection unit, wherein the tail current detection unit is configured to:
obtain real-time current values of current flowing in a secondary side of the CT;
determine an instant time constant, wherein the instant time constant is a ratio of an instant current value at a specific time instance and at a current value at a preceding time instance;
determine a deviation value by using a pair of consecutive time constants, wherein the pair of consecutive time constants are the instant time constant at the specific time instance and a time constant at the preceding time instance;
compare the deviation value with a predefined deviation threshold to determine whether the deviation value is less than the predefined deviation threshold;
based on the comparison, perform one of:
increment a counter each time when the deviation value is less than the predefined deviation threshold in consecutive time instances; and/or
reset the counter to zero when the deviation value is greater than the predefined deviation threshold; and/or
detect presence of tail current in the CT when the counter exceeds a predefined count threshold.

12. The IED as claimed in claim 11, wherein the tail current detection unit is further configured to activate an output signal to indicate the presence of tail current, wherein the output signal enables a switch to supply a value “zero”, instead of the current flowing in secondary side of the CT, to one or more components using information of the current flowing in the secondary side of the CT.

13. The IED as claimed in claim 11, wherein the tail current detection unit is further configured to determine a Root Mean Square (RMS) value of the current flowing in the secondary side of the CT; and determine end of the tail current in the CT, when the RMS value of the current is substantially zero.

14. The IED as claimed in claim 13, wherein the tail current detection unit is further configured to reset a counter value to zero upon determining the end of the tail current; and deactivate output signal to indicate the end of the tail current, wherein when the output signal is deactivated, the current flowing in the secondary side of the CT is supplied to one or more components using information of the current flowing in the secondary side of the CT.

15. The IED as claimed in claim 11, wherein the tail current detection unit obtains real-time measurements upon activation of a trip signal by one or more protection functions in a relay that is electrically coupled with the CT.
